(19) United States
(12) Patent Application Publication
(10) Pub. No.: US 2017/0104112 A1
(43) Pub. Date: Apr. 13, 2017

(54) PASTE COMPOSITION FOR FORMING SOLAR CELL FRONT ELECTRODE, N-TYPE SOLAR CELL FRONT ELECTRODE FORMED BY USING THE COMPOSITION, AND SOLAR CELL INCLUDING THE FRONT ELECTRODE

(71) Applicant: PHOENIX Materials Co., Ltd., Gumi (KR)

(72) Inventors: JU YOUNG WON, Gumi (KR); BYUNG CHAN BAE, Gumi (KR); WOO MAN JUNG, Gumi (KR); HYUN SU JUNG, Gumi (KR); HYO SUNG JUNG, Gumi (KR)

(21) Appl. No.: 15/289,938

(22) Filed: Oct. 10, 2016

(30) Foreign Application Priority Data
Oct. 12, 2015 (KR) 10-2015-0142235

(51) Int. Cl. H01L 31/0224; C09D 1/00; C03C 4/14; C03C 8/10; C03C 3/074; C09D 5/24; C03C 8/18

(52) U.S. Cl. CPC H01L 31/022425; C09D 5/24; C09D 1/00; C03C 8/18; C03C 8/10; C03C 3/0745; C03C 4/14; C03C 2207/00

(57) ABSTRACT

The present invention relates to a paste composition for forming a solar cell front electrode, a solar cell front electrode formed by using the composition, and a solar cell including the front electrode.

Specifically, the paste composition includes conductive powder; an inorganic additive; and an organic vehicle, wherein the conductive powder is a metal powder including a mixture of silver (Ag) powder and aluminum (Al) powder, and the inorganic additive includes a lead (Pb)-zinc (Zn)-boron (B)-silicon (Si)-tungsten (W)-based glass frit.

### CROSS-REFERENCE TO RELATED APPLICATION

This application claims priority to and the benefit of Korean Patent Application No. 10-2015-0142235 filed in the Korean Intellectual Property Office on Oct. 12, 2015, the entire contents of which are incorporated herein by reference.

### BACKGROUND OF THE INVENTION

(a) Field of the Invention

The present invention relates to a paste composition for forming a solar cell front electrode, an N-type solar cell front electrode formed by using the composition, and a solar cell including the front electrode.

(b) Description of the Related Art

A solar cell is a photoelectric conversion device that converts solar energy into electrical energy, and thus, has received attention as an indefinite pollution-free next generation energy resource.

In order to increase an efficiency of the solar cell, it is important to be able to output as much electrical energy as possible from the solar energy, and as one method, the solar cell may have a large area.

However, as the solar cell has a large area, line resistivity and contact resistivity between a semiconductor substrate and an electrode are increased, and thus, the efficiency of the cell may be rather reduced.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a paste composition for forming a solar cell front electrode having advantages of solving the above-described problems by controlling components and contents thereof.

### Paste Composition for Forming Solar Cell Front Electrode

An exemplary embodiment of the present invention provides a paste composition for forming a solar cell front electrode, including: conductive powder; an inorganic additive; and an organic vehicle, wherein the conductive powder is a metal powder including a mixture of silver (Ag) powder and aluminum (Al) powder, and the inorganic additive includes a lead (Pb)-zinc (Zn)-boron (B)-silicon (Si)-tungsten (W)-based glass frit, wherein a total amount (100 wt %) of the glass frit includes 60 to 80 wt % of lead oxide (PbO), 15 to 25 wt % of zinc oxide (ZnO), 1 to 10 wt % of boron oxide (B₂O₃), 1 to 5 wt % of silicon oxide (SiO₂), and 0.1 to 1.0 wt % of tungsten oxide (WO₃).

The glass frit is described as follows.

A softening point (Tdsp) of the glass frit may satisfy a temperature range from more than 300° C. to less than 450° C.

A crystallization temperature (Tc) of the glass frit may satisfy a temperature range from more than 450° C. to less than 600° C.

The conductive powder is described as follows.

In the conductive powder, a weight ratio of the aluminum (Al) powder with regard to the silver (Ag) powder may be 0.01:0.99 to 5:95.

A weight ratio of the aluminum (Al) powder with regard to the silver (Ag) powder may be 0.5:99.5 to 3:97.

A particle diameter (D50) of the conductive powder may be 10 μm or less (provided that 0 μm is excluded).

Specifically, the silver powder may include at least two kinds of silver particles each having a different particle diameter.

The organic vehicle is described as follows.

The organic vehicle may include an organic binder and an organic solvent.

The organic binder may be any one material selected from the group consisting of a cellulose-based binder, an acrylate-based binder, and rosin, or a mixture of two or more thereof.

The organic solvent may be any one material selected from the group consisting of diethylene glycol monobutyl ether, diethylene glycol monobutyl ether acetate, propylene glycol monomethyl ether, terpineol, texanol, benzylalcohol, and phenoxy ethanol, or a mixture of two or more thereof. Meanwhile, the inorganic additive may further include a sintering inhibitor.

The sintering inhibitor may include silicon (Si), silicon oxide (SiO₂) or a mixture thereof.

The sintering inhibitor may have an amount of 2 wt % or less (provided that 0 wt % is excluded) with regard to a total amount (100 wt %) of the paste composition.

With regard to the total amount (100 wt %) of the paste composition, the inorganic additive may have an amount of 1 to 10 wt %, the organic vehicle may have an amount of 0.1 to 20 wt %, and the conductive powder may have a residual amount.

Here, the paste composition may further include an organic additive.

The organic additive may be any one material selected from the group consisting of a dispersing agent, a thixotropic agent, a plasticizer, a viscosity stabilizer, an anti-foaming agent, an antioxidant, and a coupling agent, or a mixture of two or more thereof.

With regard to the total amount (100 wt %) of the paste composition, the organic additive may have an amount of 0.01 to 5 wt %.

Front Electrode of Solar Cell

Another embodiment of the present invention provides a front electrode of a solar cell formed by using the paste composition as described above.

### Solar Cell

Yet another embodiment of the present invention provides a solar cell including: a semiconductor substrate; a front electrode positioned on a front side of the semiconductor substrate; and a rear electrode positioned on a rear side of the semiconductor substrate, wherein the front electrode includes a bus bar electrode, and a finger electrode, and at least one electrode of the bus bar electrode and the finger electrode is formed by using the paste composition as described above.

The semiconductor substrate may be an N-type silicon substrate.

Adherence between the semiconductor substrate and the front electrode may be 4 N or more.

A line resistivity of the front electrode may be less than 3.5 uΩ·cm.

A contact resistivity of the front electrode may be less than 5 mΩcm².

A fill factor of the solar cell may be 80% or more.

A conversion efficiency of the solar cell may be 21.0% or more.

According to embodiments of the present invention, the adherence between the semiconductor substrate and the front electrode may be improved to minimize the line resistivity and the contact resistivity, and thus, the fill factor and the conversion efficiency of the solar cell may be ultimately improved. At the same time, heat stability may be secured.

### BRIEF DESCRIPTION OF THE DRAWINGS

FIG. 1 schematically shows a solar cell according to an embodiment of the present invention.

### DETAILED DESCRIPTION OF THE EMBODIMENTS

Hereinafter, exemplary embodiments of the present invention will be described in detail. However, the following exemplary embodiments are only provided as one embodiment of the present invention, and the present invention is not limited to the following Examples.

In the drawings, the thickness of layers, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

In general, an electrode of a solar cell may be formed by a series of processes including: mixing conductive powder, glass frit, and an organic vehicle, further adding an additive if necessary to thereby prepare a paste composition, applying and patterning the paste composition on one side or both sides of a semiconductor substrate, and firing and drying the applied paste composition.

Here, the glass frit produces metal crystal particles in an emitter region by etching an anti-reflection film during the firing process and melting the conductive powder, such that adherence between the electrode (particularly, the metal crystal particle) and the semiconductor substrate may be improved, which reduces line resistivity and contact resistivity, and a firing temperature may be more reduced by softening.

When considering the process for forming the electrode, it may be appreciated that reducing the line resistivity and the contact resistivity by improving contact property between the semiconductor substrate and the electrode formed thereon is an important factor in increasing an efficiency of the solar cell.

Hereinafter, in exemplary embodiments of the present invention, it is attempted to improve a fill factor and a conversion efficiency of the solar cell, and at the same time, to secure heat stability of the solar cell, particularly, by controlling components and contents of a paste composition forming a solar cell front electrode.

Paste Composition for Forming Solar Cell Front Electrode

In an embodiment of the present invention, there is provided a paste composition for forming a solar cell front electrode, including: conductive powder; an inorganic additive; and an organic vehicle, wherein the conductive powder is a metal powder including a mixture of silver (Ag) powder and aluminum (Al) powder, and the inorganic additive includes a lead (Pb)-zinc (Zn)-boron (B)-silicon (Si)-tungsten (W)-based glass frit, wherein a total amount (100 wt %) of the glass frit includes 60 to 80 wt % of lead oxide (PbO), 15 to 25 wt % of zinc oxide (ZnO), 1 to 10 wt % of boron oxide (B₂O₃), 1 to 5 wt % of silicon oxide (SiO₂), and 0.1 to 1.0 wt % of tungsten oxide (WO₃).

When the paste composition is formed as a front electrode by including the conductive powder in which the silver (Ag) powder is mixed with the aluminum (Al) powder, and including the lead (Pb)-zinc (Zn)-boron (B)-silicon (Si)-tungsten (W)-based glass frit satisfying each content range, adherence between the semiconductor substrate and the front electrode may be excellent.

Specifically, the front electrode formed by using the paste composition may minimize the line resistivity and the contact resistivity, which ultimately contributes to improvement of the fill factor and the conversion efficiency of the solar cell. At the same time, heat stability may be secured.

More specifically, the paste composition may be formed to be a front electrode of an N-type silicon substrate. It is known that the N-type silicon substrate is one kind of high-purity substrates, and has advantages in that surface recombination caused by impurities is suppressed, which minimizes degradation of an open-circuit voltage (Voc), but has a drawback in that sheet resistance is high as 110 to 130 Ω/sq.

Here, the paste composition may reduce the line resistivity and the contact resistivity by improving adherence between the electrode and the semiconductor substrate. Specifically, since the electrode is a general metal, a Schottky barrier gap is present between a metal work function and a semiconductor work function according to heterojunction with the semiconductor substrate. The paste composition may reduce the Schottky barrier gap. Accordingly, the paste composition may reduce the Schottky barrier gap between the electrode and the semiconductor substrate to facilitate movement of electrons, such that the contact resistivity may be decreased, and as a result, the paste composition may be appropriate for forming the front electrode of the N-type silicon substrate having high sheet resistance.

These descriptions are supported through Examples to be described below and Evaluation Examples therefor.

The glass frit is described as follows.

As described above, the glass frit is the lead (Pb)-zinc (Zn)-boron (B)-silicon (Si)-tungsten (W)-based glass frit satisfying each content range, and may be soften at an appropriate softening point to contribute to reduction of the firing temperature, and may satisfy each range of the softening point and a crystallization temperature to be described below.

Specifically, the softening point (Tdsp) of the glass frit may satisfy a temperature range from more than 300° C. to less than 450° C.

In addition, the crystallization temperature (Tc) of the glass frit may satisfy a temperature range from more than 450° C. to less than 600° C.

The respective temperature ranges are supported through Examples to be described below and Evaluation Examples therefor.

Meanwhile, the glass frit may be manufactured by general methods. For example, the lead oxide (PbO), the zinc oxide (ZnO), the boron oxide (B₂O₃) and the silicon oxide (SiO₂) are mixed so as to satisfy each content range. The mixing process may be performed by using a ball mill, a planetary mill, etc.

Then, the mixed composition may be molten at a temperature range from 900° C. to 1300° C., followed by quenching at room temperature (25° C.), and grinding by using a disk mill, the planetary mill, etc., thereby finally obtaining the glass frit of which a particle diameter is controlled.

Specifically, the finally obtained glass frit may have a particle diameter (D50) of 4 μm or less (provided that 0 μm is excluded), and specifically, 1 to 2 μm, and may have a spherical shape or an amorphous shape.

Meanwhile, in general, silver (Ag) powder is used alone as conductive powder at the time of forming the front electrode of the solar cell. In contrast, in an embodiment of the present invention, the metal powder including the mixture of silver (Ag) powder and aluminum (Al) powder is used as the conductive powder.

The mixture is basically the conductive powder, and may collect photo-produced charges. In particular, the aluminum (Al) powder in the mixture contributes to further reduction of the contact resistivity of the electrode.

In the mixture, a weight ratio of the aluminum (Al) powder with regard to the silver (Ag) powder may be 0.01:0.99 to 5:95, and specifically, 0.5:99.5 to 3:97. When the weight ratio is satisfied, excellent electric conductivity may be exhibited, and the contact resistivity of the electrode may be further reduced.

Meanwhile, when the aluminum (Al) powder is mixed in an excessive amount which is out of the above content range, series resistance may be increased or shunting phenomenon may occur, which may deteriorate an efficiency. On the contrast, when the aluminum (Al) powder is mixed in a small amount which is less than the above content range, effectiveness may be insignificant.

Meanwhile, the particle diameter (D50) of the conductive powder may be 10 μm or less (provided that 0 μm is excluded), and specifically, 1 to 5 μm.

Here, the silver powder may include one kind of silver particle having the same particle diameter, but may also include at least two kinds of silver particles each having a different particle diameter. As described above, when the at least two kinds of silver particles each having a different particle diameter are used, compactness may be enhanced to improve the series resistance, and homogeneity may be improved to increase a margin width of the shunting phenomenon.

More specifically, with regard to a total amount (100 mol %) of the silver powder, the silver particles having the particle diameter (D50) of 3 μm or less (provided that 0 μm is excluded) and having an amount of 50 mol % or less (provided that 0 mol % is excluded) may be mixed with the silver particles having the particle diameter (D50) of more than 3 μm to 5 μm or less and having an amount of more than 50 mol % to less than 100 mol %, and may be used as the silver powder.

The respective particles included in the silver powder and the aluminum powder may have any shape of a spherical shape, a plate shape and an amorphous shape.

The organic vehicle is mixed with the conductive powder to provide an appropriate viscosity to form a paste, and may include an organic binder and an organic solvent dissolving the organic binder.

Specifically, the organic binder may be any one material selected from the group consisting of a cellulose-based binder, an acrylate-based binder, and rosin, or a mixture of two or more of thereof.

More specifically, ethylcellulose which is one kind of the cellulose-based binder is used, provided that one kind of ethyl cellulose having the same ethoxyl content (%) may be used, or at least two kinds of ethyl celluloses each having a different ethoxyl content may be mixed to be used.

In addition, the organic solvent may be any one material selected from the group consisting of diethylene glycol monobutyl ether, diethylene glycol monobutyl ether acetate, propylene glycol monomethyl ether, terpineol, texanol, benzylalcohol, and phenoxy ethanol, or a mixture of two or more thereof.

Meanwhile, the inorganic additive may further include a sintering inhibitor.

The sintering inhibitor may include silicon (Si), silicon oxide (SiO₂) or a mixture thereof.

Specifically, the sintering inhibitor may have an amount of 2 wt % or less (provided that 0 wt % is excluded) with regard to the total amount (100 wt %) of the paste composition. When the sintering inhibitor is included in the above-described content range, a junction shunting phenomenon of the electrode may be effectively suppressed.

With regard to the total amount (100 wt %) of the paste composition, the inorganic additive may have an amount of 1 to 10 wt %, the organic vehicle may have an amount of 0.1 to 20 wt %, and the conductive powder may have a residual amount.

The paste composition satisfying each of the above content ranges may have excellent adherence with the electrode due to the inorganic additive, and an appropriate viscosity due to the organic vehicle, and excellent electric conductivity due to the conductive powder.

Here, the paste composition may further include an organic additive to have an improved printing characteristic.

Specifically, the organic additive may be any one material selected from the group consisting of a dispersing agent, a thixotropic agent, a plasticizer, a viscosity stabilizer, an anti-foaming agent, an antioxidant, and a coupling agent, or a mixture of two or more thereof.

More specifically, with regard to the total amount (100 wt %) of the paste composition, the organic additive may have an amount of 0.01 to 5 wt %.

Electrode of Solar Cell

In still another embodiment of the present invention, there is provided a front electrode of a solar cell formed by using the paste composition as described above.

The description overlapped with the above-described content of the paste composition will be omitted, and the front electrode and a method for forming the same are described as follows.

Solar Cell

In still another embodiment of the present invention, there is provided a solar cell including: a semiconductor substrate; a front electrode positioned on a front side of the semiconductor substrate; and a rear electrode positioned on a rear side of the semiconductor substrate, wherein the front electrode includes a bus bar electrode, and a finger electrode, and at least one electrode of the bus bar electrode and the finger electrode is formed by using the paste composition as described above.

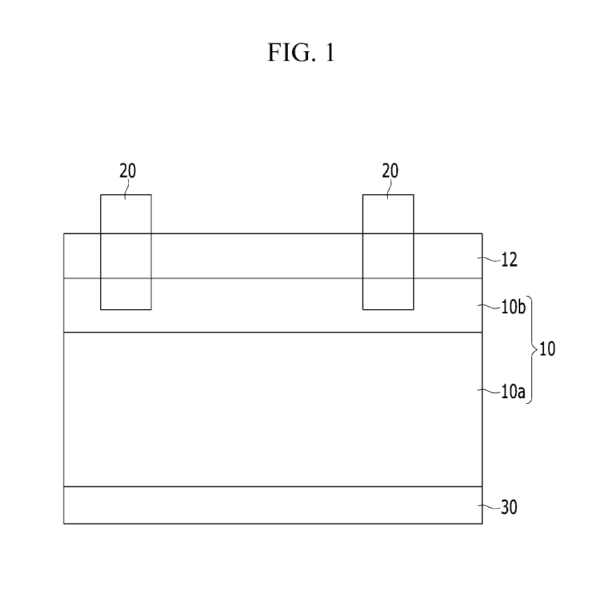

FIG. 1 is a cross-sectional view of the solar cell.

Hereinafter, a solar cell according to an embodiment is described with reference to FIG. 1. Meanwhile, the solar cell shown in FIG. 1 is only provided as an example, and thus, the solar cell is not limited thereto.

Hereinafter, positional relationships between an upper part and a lower part on the basis of the semiconductor substrate 10 are described for convenience of explanation, but the present invention is not limited thereto. In addition, a side receiving solar energy in the semiconductor substrate 10 is referred to as a front side and an opposite side to the front side is referred to as a rear side.

Referring to FIG. 1, the solar cell according to an embodiment includes a semiconductor substrate 10 including a lower semiconductor layer 10a and an upper semiconductor layer 10b.

The semiconductor substrate 10 may be made of a semiconductor material. The semiconductor material may be specifically crystalline silicon or compound semiconductor, wherein as the crystalline silicon, an N-type silicon substrate having a wafer form may be used.

More specifically, when the semiconductor substrate 10 is the N-type silicon substrate, the lower semiconductor layer 10a and the upper semiconductor layer 10b may be doped with N-type impurities, and the upper semiconductor layer 10b may be doped with P-type impurities.

Meanwhile, an anti-reflection film 12 may be formed on a front side of the semiconductor substrate 10. The anti-reflection film 12 may be formed on the front side of the semiconductor substrate 10 receiving solar energy to reduce light reflectance and to increase selectivity of a specific wavelength region. Further, a contact characteristic with the silicon present on a surface of the semiconductor substrate 10 may be improved to increase an efficiency of the solar cell.

Accordingly, the anti-reflection film 12 may be made of a material that absorbs a small amount of light and has an insulation property. The anti-reflection film may be, for example, silicon nitride (SiNₓ), silicon oxide (SiO₂), titanium oxide (TiO₂), aluminum oxide (Al₂O₃), magnesium oxide (MgO), cerium oxide (CeO₂), and a combination thereof, and may be formed in a single layer or a plurality of layers.

The anti-reflection film 12 may have a thickness of 200 to 1500 Å, but the thickness is not limited thereto.

A plurality of front electrodes 20 including a plurality of finger electrodes may be formed on the anti-reflection film 12. The front electrode 20 may be extended side by side along one direction of the semiconductor substrate 10, but is not limited thereto.

The bus bar electrode (not shown) may be formed on the finger electrode. The bus bar electrode is to connect adjacent solar cells when assembling a plurality of solar cells.

Here, at least one front electrode of the bus bar electrode and the finger electrode may be formed by using the above-described paste composition through a screen printing method.

Specifically, the front electrode formed by using above-described paste composition may be the finger electrode. In this case, the line resistivity of the front electrode may be less than 3.5 uΩ·cm, and the contact resistivity thereof may be less than 5 mΩcm². Here, the fill factor of the solar cell may be 80% or more, and the conversion efficiency thereof may be 21.0% or more. These descriptions are supported through Examples to be described below and Evaluation Examples therefor.

Meanwhile, a rear electrode 30 may be formed below the semiconductor substrate 10. The rear electrode 30 may be formed by using a paste composition which is different from the above-described paste composition, through the screen printing method. Here, the conductive powder included in the composition may be an opaque metal such as aluminum (Al), etc.

Hereinafter, preferable Examples, Comparative Examples compared to these Examples, and Evaluation Examples obtained by comparing and evaluating the Examples and the Comparative Examples are described. However, these following Examples are merely provided as preferable examples of the present invention. Therefore, it is to be noted that the present invention is not limited to the following Examples

### Examples 1 to 13

### (1) Manufacture of Glass Frit

Lead oxide (PbO), zinc oxide (ZnO), boron oxide (B₂O₃) and silicon oxide (SiO₂) were mixed so as to satisfy compositions according to Examples 1 to 13 of Table 1 below, respectively. The mixing process was performed by using a weightlessness mixer with sufficient time so that all components in the glass frit composition were completely mixed.

Next, the components after the mixing process was finished were put into a platinum crucible, and then, a melting process was performed at a temperature of 950 to 1,250° C. A melting time was 30 minutes. The glass composition molten in the melting process was quenched through dry quenching and wet quenching. The quenched glass molten material was ground into a powder state by using a jet mil, and finally, a glass frit having a particle diameter (D50) of 2.0±0.5 μm was able to be obtained.

### (2) Preparation of Paste Composition

Conductive powder, an organic vehicle, and an additive were put into each glass frit of Examples 1 to 13, and mixed with each other to prepare each paste composition.

Specifically, with regard to a total amount (100 wt %) of each paste composition, the glass frit had an amount of 4.0 wt %, the conductive powder had an amount of 88.82 wt %, the organic vehicle had an amount of 2.10 wt %, and the additive had an amount of 5.08 wt %.

Here, as the conductive powder, silver (Ag) powder and aluminum (Al) powder were mixed at a weight ratio of 2:98 (aluminum powder:silver powder), and the mixed powder was used. Here, the silver powder was used by mixing silver powder having a particle diameter (D50) of 2.0 μm and silver powder having a particle diameter (D50) of 4.0 μm at a weight ratio of 30:70 (silver powder having a particle diameter (D50) of 2.0 μm:silver powder having a particle diameter (D50) of 4.0 μm). In addition, as the aluminum (Al) powder, aluminum (Al) powder having a particle diameter (D50) of 4.0 μm was used.

For the organic vehicle, an organic binder (STD-300) and an organic solvent (butyl carbitol acetate) were mixed at a weight ratio of 7:93, and for the additive, a thickener, a dispersing agent, a leveling agent, a lubricant, a plasticizer, and a viscoelasticity adjuster were appropriately mixed to be used.

### (3) Formation of Front Electrode of Solar Cell

Before forming the front electrode, a rear electrode was formed on a rear side of an N-type silicon wafer (sheet resistance: 110 Ω/sq.) which is one kind of the semiconductor substrate, by applying and drying an aluminum paste composition.

Specifically, as the aluminum paste composition, a commercial product, DSCP-A151 (Dongjin Semichem Co., Ltd.) paste was used, and the applying was performed through screen printing with predetermined patterns, and the drying was performed by maintaining the composition at 130° C. for 4 minutes in an infrared ray drying furnace, followed by cooling.

Then, each paste composition of Examples 1 to 8 prepared by (2) above was used to form each front electrode.

Specifically, each paste composition was applied on the front side of the silicon wafer including the rear electrode formed thereon. The applying was performed through screen printing with predetermined patterns.

In a state in which all of the rear electrode and the front electrode were formed, firing was performed by raising a temperature in a belt-type firing furnace at a speed of 185 inch/min up to 740° C.

### Comparative Examples 1 to 21

Paste compositions and front electrodes were manufactured by the same method as Examples 1 to 13 except that glass frit compositions were prepared with compositions of Comparative Examples 1 to 21 of Table 1 below, and then solar cells were manufactured.

TABLE 1

| | | Content of each component in glass frit (unit: wt | | | | |
|---|---|---|---|---|---|---|
| | | %, based on total amount (100 wt %) of glass frit) | | | | |
| Classification | | PbO | ZnO | B₂0₃ | SiO₂ | WO₃ |
| Example | 1 | 73.2 | 22.9 | 1.4 | 2.3 | 0.3 |
| Example | 2 | 75.5 | 14.2 | 7.5 | 2.4 | 0.5 |
| Example | 3 | 67.6 | 21.1 | 8.5 | 2.1 | 0.7 |
| Example | 4 | 75.8 | 18.9 | 1.3 | 3.8 | 0.3 |
| Example | 5 | 71.0 | 22.2 | 2.0 | 4.4 | 0.4 |
| Example | 6 | 72.2 | 13.5 | 9.0 | 4.5 | 0.7 |
| Example | 7 | 66.2 | 20.7 | 8.3 | 4.1 | 0.7 |
| Example | 8 | 72.7 | 22.7 | 2.0 | 2.3 | 0.3 |
| Example | 9 | 74.1 | 13.9 | 9.3 | 2.3 | 0.5 |
| Example | 10 | 67.6 | 21.1 | 8.5 | 2.1 | 0.7 |
| Example | 11 | 71.2 | 22.2 | 2.0 | 4.4 | 0.2 |
| Example | 12 | 73.7 | 13.8 | 7.4 | 4.6 | 0.5 |
| Example | 13 | 66.2 | 20.7 | 8.3 | 4.1 | 0.7 |
| Range in claims | | 60-80 | 15-25 | 1-10 | 1-5 | 0.1-1.0 |
| Comparative | 1 | 77.92 | 8.66 | 12.99 | — | 0.43 |
| Example | | | | | | |
| Comparative | 2 | 60.61 | 25.97 | 12.99 | — | 0.43 |
| Example | | | | | | |
| Comparative | 3 | 86.96 | 9.66 | — | 2.42 | 0.97 |
| Example | | | | | | |
| Comparative | 4 | 81.63 | 13.61 | — | 3.40 | 1.36 |
| Example | | | | | | |
| Comparative | 5 | 75.95 | 21.10 | — | 2.11 | 0.84 |
| Example | | | | | | |
| Comparative | 6 | 64.78 | 20.24 | 12.15 | 2.02 | 0.81 |
| Example | | | | | | |
| Comparative | 7 | 56.60 | 23.58 | 14.15 | 4.72 | 0.94 |
| Example | | | | | | |
| Comparative | 8 | 84.51 | — | 7.04 | 7.04 | 1.41 |
| Example | | | | | | |
| Comparative | 9 | 79.21 | — | 9.90 | 9.90 | 0.99 |
| Example | | | | | | |
| Comparative | 10 | 66.33 | 30.61 | 0.51 | 2.04 | 0.51 |
| Example | | | | | | |
| Comparative | 11 | 70.27 | 10.81 | 16.22 | 2.16 | 0.54 |
| Example | | | | | | |
| Comparative | 12 | 77.42 | — | 19.35 | 2.58 | 0.65 |
| Example | | | | | | |
| Comparative | 13 | 82.30 | — | 15.43 | 2.06 | 0.21 |
| Example | | | | | | |
| Comparative | 14 | 59.70 | 24.88 | 4.98 | 9.95 | 0.50 |
| Example | | | | | | |
| Comparative | 15 | 74.07 | 21.16 | — | 4.23 | 0.53 |
| Example | | | | | | |
| Comparative | 16 | 60.30 | 35.18 | — | 4.02 | 0.50 |
| Example | | | | | | |
| Comparative | 17 | 78.74 | 15.75 | — | 4.72 | 0.79 |
| Example | | | | | | |
| Comparative | 18 | 56.28 | 30.30 | 8.66 | 4.33 | 0.43 |
| Example | | | | | | |
| Comparative | 19 | 74.29 | 11.43 | 9.14 | 4.57 | 0.57 |
| Example | | | | | | |
| Comparative | 20 | 71.43 | 16.48 | 8.79 | 3.30 | — |
| Example | | | | | | |
| Comparative | 21 | 72.22 | 22.22 | 4.44 | 1.11 | — |
| Example | | | | | | |

### Evaluation Example 1: Evaluation of Adherence, Line Resistivity, and Contact Resistivity

With each electrode or each solar cell of Examples 1 to 13, and Comparative Examples 1 to 21, adherence, line resistivity, and contact resistivity were evaluated, and respective evaluation results were shown in Table 2 below. Here, specific evaluation condition was as follows.

Adherence:

Ribbons (having a width of 1.5 mm, and a thickness of 0.2 mm) were aligned in a straight line on an island type bus bar of each front electrode of the solar cell, and then, bonding was performed by applying hot air at 150° C. using a tabbing machine. Each bonded wafer was subjected to a peel test (180 degree peel condition) using a universal testing machine (NTS technology Co.). With regard to this, the adherence values recorded in Table 3 below were the highest adherence values among values measured in the peel test, respectively.

Line Specific Resistivity:

Each electrode paste composition including the silver powder was printed, dried, and fired on a printing plate having a length of 20000 μm and a width of 60 μm, and then, line resistivity was measured by using a multimeter (Tektronix DMM 4020 device). Separately, each area was measured by laser microscope (KEYENCE VK-X100). Then, the line specific resistivity was calculated by putting each measurement value into Calculation Equation 1 below, and recorded in Table 2 below.

Line specific resistivity=(Resistance×Area)/Length [Calculation Equation 1]

Contact Specific Resistivity:

The contact resistivity was measured by using a transfer length method (TLM) which is one of widely known methods. Specifically, first, each electrode paste composition including the silver powder was printed on the wafer with bar patterns (L*Z, 500 μm*3000 μm), followed by drying and firing. Here, in order to suppress an interference phenomenon at the time of measuring the contact resistivitiy, edges of the bar patterns were insulated by irradiation with laser twice at frequency of 200 kHz with a pulse width of 50% using a laser etching machine (Hardram Co., Ltd.). Then, the resistance was measured by using the multimeter (Tektronix DMM 4020 device), and a slope and an intercept of the resistance according to intervals were measured to calculate the contact resistivity (Ri, Rₜₒₜₐₗ). The measured contact resistivity and the area were put into Calculation Equation 2 below to obtain the contact specific resistivity, which was recorded in Table 2 below.

Contact specific resistivity=Contact resistance×Area [Calculation Equation 2]

TABLE 2

| | | Line-specific | Contact-specific | |
|---|---|---|---|---|
| | | resistivity | resistivity | Adherence |
| Classification | | (unit: uΩ · cm) | (unit: mΩ · cm²) | (unit: N) |
| Example | 1 | 3.2 | 3.1 | 5.20 |
| Example | 2 | 3.5 | 4.2 | 5.80 |
| Example | 3 | 3.6 | 4.5 | 6.30 |
| Example | 4 | 3.1 | 3.6 | 5.70 |
| Example | 5 | 3.4 | 2.8 | 6.60 |
| Example | 6 | 3.3 | 2.2 | 4.90 |
| Example | 7 | 3.4 | 2.9 | 7.20 |
| Example | 8 | 3.2 | 1.9 | 8.30 |
| Example | 9 | 3.2 | 4.3 | 4.70 |
| Example | 10 | 3.4 | 3.6 | 5.90 |
| Example | 11 | 3.3 | 2.7 | 6.30 |
| Example | 12 | 3.2 | 1.8 | 5.80 |
| Example | 13 | 3.4 | 2.1 | 7.20 |
| Range in claims | | <3.5 | <5 | >4 |
| Comparative | 1 | 3.6 | 15.8 | 4.8 |
| Example | | | | |
| Comparative | 2 | 3.8 | 11.2 | 3.5 |
| Example | | | | |
| Comparative | 3 | 3.7 | 12.3 | 3.2 |
| Example | | | | |
| Comparative | 4 | 3.7 | 8.7 | 3.1 |
| Example | | | | |
| Comparative | 5 | 3.7 | 7.1 | 3.8 |
| Example | | | | |
| Comparative | 6 | 3.8 | 14.8 | 6.2 |
| Example | | | | |
| Comparative | 7 | 3.3 | 18.5 | 5.8 |
| Example | | | | |
| Comparative | 8 | 3.4 | 589.5 | 4.9 |
| Example | | | | |
| Comparative | 9 | 3.4 | 459.6 | 5.8 |
| Example | | | | |
| Comparative | 10 | 3.3 | 3.5 | 3.2 |
| Example | | | | |
| Comparative | 11 | 3.3 | 4.8 | 2.6 |
| Example | | | | |
| Comparative | 12 | 3.4 | 448.9 | 1.7 |
| Example | | | | |
| Comparative | 13 | 3.3 | 320.3 | 2.2 |
| Example | | | | |
| Comparative | 14 | 3.4 | 21.5 | 5.6 |
| Example | | | | |
| Comparative | 15 | 3.4 | 4.3 | 2.8 |
| Example | | | | |
| Comparative | 16 | 3.6 | 3.4 | 3.8 |
| Example | | | | |
| Comparative | 17 | 3.3 | 4.2 | 2.4 |
| Example | | | | |
| Comparative | 18 | 3.6 | 16.4 | 2.6 |
| Example | | | | |
| Comparative | 19 | 3.5 | 9.3 | 4.2 |
| Example | | | | |
| Comparative | 20 | 3.4 | 7.5 | 6.2 |
| Example | | | | |
| Comparative | 21 | 3.3 | 5.2 | 5.3 |
| Example | | | | |

According to Table 2 above, Comparative Examples 1 to 21 had low adherence that could not reach those of Example 1 to 13, or had high line resistivity or high contact resistivity.

In contrast, all of Examples 1 to 13 had excellent adherence exceeding 4 N, and further, had low line resistivity less than 3.5 uΩ·cm, and low contact resistivity less than 5 mΩ·cm².

These results were made due to differences of the glass frit compositions, which indicated that unlike Comparative Examples 1 to 21, Examples 1 to 13 satisfied Table 1, such that the adherence even between the N-type silicon substrate having high sheet resistance and the front electrode was excellent, and the line resistivity and the contact resistivity were reduced.

### Evaluation Example 2: Evaluation of Softening Point and Crystallization Temperature

With each glass frit of Examples 1 to 13, and Comparative Examples 1 to 21, the softening point and the crystallization temperature were evaluated, and respective evaluation results were shown in Table 3 below. Here, specific evaluation condition was as follows.

Softening Point:

Each glass frit was applied onto an aluminum pan, and the softening point was measured by raising a temperature at a speed of 10° C./min up to 580° C. using a differential scanning calorimeter (DSC, TA instruments). During the measurement, peak points at which an endothermic reaction was finished were analyzed to confirm the Tdsp temperatures, which were recorded in Table 3 below.

Crystallization Temperature:

The Tc temperature was confirmed under the same temperature-rising speed and temperature by using the same DSC as those used at the time of measuring the softening point, and analyzing peak points at which the endothermic reaction was finished during the measurement, and recorded in Table 3 below.

TABLE 3

| | | Softening point | Crystallization temperature |
|---|---|---|---|
| Classification | | (Tdsp, ° C.) | (Tc, ° C.) |
| Example | 1 | 321.2 | 486.5 |
| Example | 2 | 376.4 | 500.5 |
| Example | 3 | 355.6 | 492.3 |
| Example | 4 | 380.9 | 500.2 |
| Example | 5 | 324.2 | 488.8 |
| Example | 6 | 398.6 | 521.4 |
| Example | 7 | 367.7 | 476.7 |
| Example | 8 | 330.2 | 477.7 |
| Example | 9 | 388.8 | 512.5 |
| Example | 10 | 367.7 | 502.7 |
| Example | 11 | 356.6 | 520.4 |
| Example | 12 | 406.6 | 543.5 |
| Example | 13 | 381.1 | 569.7 |
| Range in claims | | >300, <450 | >450, <600 |
| Comparative | 1 | 378.9 | 488.7 |
| Example | | | |
| Comparative | 2 | 432.3 | 465.9 |
| Example | | | |
| Comparative | 3 | 368.5 | 500.3 |
| Example | | | |
| Comparative | 4 | 350.4 | 488.7 |
| Example | | | |
| Comparative | 5 | 366.7 | 498.3 |
| Example | | | |
| Comparative | 6 | 423.5 | 567.4 |
| Example | | | |
| Comparative | 7 | 493.5 | 590.6 |
| Example | | | |
| Comparative | 8 | 376.6 | — |
| Example | | | |
| Comparative | 9 | 435.5 | — |
| Example | | | |
| Comparative | 10 | 377.5 | 478.3 |
| Example | | | |
| Comparative | 11 | 434.5 | 532.4 |
| Example | | | |
| Comparative | 12 | 489.9 | — |
| Example | | | |
| Comparative | 13 | 443.2 | — |
| Example | | | |
| Comparative | 14 | 469.2 | 563.2 |
| Example | | | |
| Comparative | 15 | 380.6 | 523.6 |
| Example | | | |
| Comparative | 16 | 367.4 | 480.3 |
| Example | | | |
| Comparative | 17 | 377.3 | 534.5 |
| Example | | | |
| Comparative | 18 | 412.2 | 480.9 |
| Example | | | |
| Comparative | 19 | 402.1 | 543.2 |
| Example | | | |
| Comparative | 20 | 396.5 | 527.8 |
| Example | | | |
| Comparative | 21 | 366.4 | 507.8 |
| Example | | | |

According to Table 3, in Comparative Examples 1 to 21, the low softening point of 300° C. or less or the high softening point of 450° C. or more was measured, and the low crystallization temperature of 450° C. or less or the high crystallization temperature of 600° C. or more was measured.

In contrast, in Examples 1 to 13, the softening point having an appropriate range from more than 300° C. to less than 450° C. was measured, and the crystallization temperature of more than 450° C. to less than 600° C. was measured.

These results also were made due to differences of the glass frit compositions, which indicated that unlike Comparative Examples 1 to 21, Examples 1 to 13 satisfied Table 1, such that the glass frits were softened at an appropriate softening point to more reduce the firing temperature, and to exhibit excellent heat stability.

### Evaluation Example 3: Evaluation of Fill Factor and Conversion Efficiency

With each solar cell of Examples 1 to 13, and Comparative Examples 1 to 21, the fill factor and the conversion efficiency were evaluated, and respective evaluation results were shown in Table 4 below. Here, specific evaluation condition was as follows.

TABLE 4

| | Classification | | Fill Factor | Conversion efficiency |
|---|---|---|---|---|
| | Example | 1 | 80.52% | 21.89% |
| | Example | 2 | 80.12% | 21.81% |
| | Example | 3 | 80.33% | 21.80% |
| | Example | 4 | 80.51% | 21.69% |
| | Example | 5 | 80.87% | 21.92% |
| | Example | 6 | 81.02% | 21.99% |
| | Example | 7 | 80.66% | 21.86% |
| | Example | 8 | 81.32% | 22.04% |
| | Example | 9 | 80.31% | 21.89% |
| | Example | 10 | 80.75% | 21.98% |
| | Example | 11 | 81.06% | 22.03% |
| | Example | 12 | 81.24% | 22.12% |
| | Example | 13 | 81.16% | 22.06% |
| Range in claims | | | >80% | >21% |
| | Comparative | 1 | 78.89% | 20.46% |
| | Example | | | |
| | Comparative | 2 | 78.92% | 20.68% |
| | Example | | | |
| | Comparative | 3 | 78.67% | 19.66% |
| | Example | | | |
| | Comparative | 4 | 79.14% | 21.21% |
| | Example | | | |
| | Comparative | 5 | 79.66% | 21.03% |
| | Example | | | |
| | Comparative | 6 | 79.42% | 20.61% |
| | Example | | | |
| | Comparative | 7 | 78.34% | 19.98% |
| | Example | | | |
| | Comparative | 8 | 72.65% | 15.97% |
| | Example | | | |
| | Comparative | 9 | 73.12% | 17.39% |
| | Example | | | |
| | Comparative | 10 | 80.45% | 21.13% |
| | Example | | | |
| | Comparative | 11 | 80.18% | 21.06% |
| | Example | | | |
| | Comparative | 12 | 73.21% | 17.41% |
| | Example | | | |
| | Comparative | 13 | 74.89% | 18.50% |
| | Example | | | |
| | Comparative | 14 | 76.34% | 19.84% |
| | Example | | | |
| | Comparative | 15 | 80.25% | 21.28% |
| | Example | | | |
| | Comparative | 16 | 80.65% | 21.39% |
| | Example | | | |
| | Comparative | 17 | 80.49% | 21.35% |
| | Example | | | |
| | Comparative | 18 | 78.02% | 19.69% |
| | Example | | | |
| | Comparative | 19 | 79.39% | 19.98% |
| | Example | | | |
| | Comparative | 20 | 79.89% | 20.19% |
| | Example | | | |
| | Comparative | 21 | 80.05% | 20.63% |
| | Example | | | |

According to Table 4 above, in Comparative Examples 1 to 21, the low fill factor of 80% or less was measured, and the low conversion efficiency of 21% or less was measured.

In contrast, in Examples 1 to 13, the high fill factor of more than 80% was measured, and the high conversion efficiency of more than 21% was measured.

These results were also made due to differences of the glass frit compositions, which indicated that unlike Comparative Examples 1 to 21, Examples 1 to 13 satisfied Table 1, such that the adherence between the electrode and the semiconductor substrate was excellent, and the line resistivity and the contact resistivity were reduced, and as a result, the fill factor and the conversion efficiency were improved.

The present invention is not limited to the exemplary embodiments disclosed herein but will be implemented in various forms. Those skilled in the art will appreciate that various modifications and alterations may be made without departing from the technical spirit or essential feature of the present invention. Therefore, the exemplary embodiments described herein are provided by way of example only in all aspects and should not be construed as being limited thereto.

### DESCRIPTION OF SYMBOLS

10: Semiconductor substrate 10a: Lower semiconductor layer 10b: Upper semiconductor layer
12: Anti-reflection film 20: Front electrode 30: Rear electrode

What is claimed is:

1. A paste composition for forming a solar cell front electrode, comprising:
conductive powder; an inorganic additive; and an organic vehicle,
wherein the conductive powder is a metal powder including a mixture of silver (Ag) powder and aluminum (Al) powder, and
the inorganic additive includes a lead (Pb)-zinc (Zn)-boron (B)-silicon (Si)-tungsten (W)-based glass frit, wherein
a total amount (100 wt %) of the glass frit includes 60 to 80 wt % of lead oxide (PbO), 15 to 25 wt % of zinc oxide (ZnO), 1 to 10 wt % of boron oxide (B₂O₃), 1 to 5 wt % of silicon oxide (SiO₂), and 0.1 to 1.0 wt % of tungsten oxide (WO₃).

2. The paste composition for forming a solar cell front electrode of claim 1, wherein:
a softening point (Tdsp) of the glass frit satisfies
a temperature range from more than 300° C. to less than 450° C.

3. The paste composition for forming a solar cell front electrode of claim 1, wherein:
a crystallization temperature (Tc) of the glass frit satisfies
a temperature range from more than 450° C. to less than 600° C.

4. The paste composition for forming a solar cell front electrode of claim 1, wherein:
in the conductive powder,
a weight ratio of the aluminum (Al) powder with regard to the silver (Ag) powder is 0.01:0.99 to 5:95.

5. The paste composition for forming a solar cell front electrode of claim 1, wherein:
in the conductive powder,
a weight ratio of the aluminum (Al) powder with regard to the silver (Ag) powder is 0.5:99.5 to 3:97.

6. The paste composition for forming a solar cell front electrode of claim 1, wherein:
a particle diameter (D50) of the conductive powder is
10 μm or less (provided that 0 μm is excluded).

7. The paste composition for forming a solar cell front electrode of claim 1, wherein:
in the conductive powder,
the silver powder includes at least two kinds of silver particles each having a different particle diameter.

8. The paste composition for forming a solar cell front electrode of claim 1, wherein:
the organic vehicle includes
an organic binder and an organic solvent.

9. The paste composition for forming a solar cell front electrode of claim 1, wherein:
with regard to a total amount (100 wt %) of the paste composition,
the inorganic additive has an amount of 1 to 10 wt %, the organic vehicle has an amount of 0.1 to 20 wt %, and the conductive powder has a residual amount.

10. The paste composition for forming a solar cell front electrode of claim 1, further comprising:
an organic additive.

11. The paste composition for forming a solar cell front electrode of claim 10, wherein:
the organic additive is
any one material selected from the group consisting of a dispersing agent, a thixotropic agent, a plasticizer, a viscosity stabilizer, an anti-foaming agent, an antioxidant, and a coupling agent, or a mixture of two or more thereof.

12. The paste composition for forming a solar cell front electrode of claim 10, wherein:
with regard to a total amount (100 wt %) of the paste composition,
the organic additive has an amount of 0.01 to 5 wt %.

13. A front electrode of a solar cell formed by using the paste composition of claim 1.

14. A solar cell comprising:
a semiconductor substrate;
a front electrode positioned on a front side of the semiconductor substrate; and
a rear electrode positioned on a rear side of the semiconductor substrate, wherein
the front electrode includes a bus bar electrode, and a finger electrode, and
at least one electrode of the bus bar electrode and the finger electrode is formed by using the paste composition of claim 1.

15. The solar cell of claim 14, wherein:
the semiconductor substrate is
an N-type silicon substrate.

16. The solar cell of claim 14, wherein:
adherence between the semiconductor substrate and the front electrode is
4 N or more.

17. The solar cell of claim 14, wherein:
a line resistivity of the front electrode is
less than 3.5 uΩ·cm (provided that 0 uΩ·cm is excluded).

18. The solar cell of claim 14, wherein:
a contact resistivity of the front electrode is
less than 5 mΩcm² (provided that 0 mΩcm² is excluded).

19. The solar cell of claim 14, wherein:
a fill factor of the solar cell is
80% or more.

20. The solar cell of claim 14, wherein:
an efficiency of the solar cell is
21.0% or more.
